(19) United States
(12) Patent Application Publication
(10) Pub. No.: US 2003/0234427 A1
(43) Pub. Date: Dec. 25, 2003

(54) Semiconductor device configured to allow well potential control in accordance with operation mode

(75) Inventor: Takashi Kono, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/321,545

(22) Filed: Dec. 18, 2002

(30) Foreign Application Priority Data
Jun. 21, 2002 (JP) 2002-181493

(51) Int. Cl. H01L 29/76; H01L 29/94; H01L 31/062; H01L 31/113; H01L 31/119

(52) U.S. Cl. 257/367

(57) ABSTRACT

A charge transfer portion is provided, which is capable of electrically connecting, in response to a mode transition, an N well to a P well where a transistor constituting a CMOS logic circuit is formed. The charge transfer portion feeds excess charges in the N well to the P well in the mode transition, in which it is necessary to lower a potential in the N well and to raise a potential in the P well. Therefore, the mode transition can quickly be achieved without wasting the charges.

### BACKGROUND OF THE INVENTION

1. Field of the Invention

The present invention relates to a semiconductor device operating at high speed with low power consumption.

2. Description of the Background Art

An integrated circuit used in portable equipment is basically driven by a battery. In order to realize long-duration drive by the battery, the integrated circuit is required to operate with low power consumption. To that end, supply voltage to the integrated circuit must also be low, and therefore, power supply potential used therein should be lowered. Meanwhile, there is a tendency that a large amount of moving images and the like are handled in the portable equipment in recent years. The integrated circuit incorporated therein is also required to operate with higher speed.

In order to meet these requirements, a P channel MOS transistor and an N channel MOS transistor constituting a CMOS (Complementary Metal-Oxide Semiconductor Device) logic circuit commonly used in the integrated circuit need to have sufficient drivability even in an operation with low voltage. In order to operate the transistors in the CMOS logic circuit at high speed, threshold voltages |Vthp| (absolute value) and Vthn of the P channel MOS transistor and the N channel MOS transistor should be set as low as possible. When a transistor with a low threshold voltage is used, however, an off-leak current will be produced between source and drain of the transistor. Consequently, particularly in a stand-by mode, power consumption cannot sufficiently be reduced, and battery drive duration of the portable equipment will be short.

In order to solve the above-described problems, some circuit models capable of enhancing current drivability of the transistor and reducing the off-leak current have been proposed, including, for example, an MT (multi threshold voltage)-CMOS model, in which transistors with different threshold voltages are combined, and a VT (variable threshold voltage) model, in which a well potential is varied in accordance with an operation mode.

The MT-CMOS model is disclosed by S. Mutoh et al. in IEEE Journal of Solid-State Circuits, vol. 30, pp. 847-854 (1995), and the VT model is disclosed by T. Kuroda et al. in IEEE Journal of Solid-State Circuits, vol. 31, pp. 1770-1779 (1996).

The VT model will now be described, in which the threshold voltage is set to a different level by switching the well potential of the MOS transistors between an operation mode (an active mode) requiring a high-speed operation and a waiting mode (a stand-by mode) simply maintaining a state within a circuit and giving the top priority to low power consumption.

More specifically, the VT model reduces the off-leak current of the transistor by setting |Vthp| and Vthn high in the stand-by mode, and achieves the high-speed operation of the transistor by setting the same low in the active mode.

FIG. 12 shows a configuration in the VT model. As shown in FIG. 12, a semiconductor device 210 adopting the VT model implementing compatibility between the high-speed operation and low power consumption of the transistor includes a P channel MOS transistor 4 and an N channel MOS transistor 5 constituting a CMOS logic circuit; an N well potential control portion 1e controlling a potential of an N well having P channel MOS transistor 4 formed therein; and a P well potential control portion 2e controlling a potential of a P well having N channel MOS transistor 5 formed therein. P channel MOS transistor 4 and N channel MOS transistor 5 are connected in series between a supply voltage Vcc and a ground voltage GND.

N well potential control portion 1e is connected to an N well portion having P channel MOS transistor 4 formed therein. P well potential control portion 2e is connected to a P well portion having N channel MOS transistor 5 formed therein.

In the specification, hereinafter, the potential of the N well having the P channel MOS transistor formed therein is simply referred to as Vbn, while the potential of the P well having the N channel MOS transistor formed therein is also simply referred to as Vbp.

Referring to FIG. 13, N well potential control portion 1e includes a well potential detecting circuit 45 monitoring Vbn, an AND circuit 46, a ring oscillator 47 activated by an output signal of the AND circuit, a charge pump circuit 48 activated by an output signal of ring oscillator 47, and a discharging circuit 70 for lowering Vbn.

Well potential detecting circuit 45 sets control signals DET2 and DET3 from low to high, in response to change of Vbn. AND circuit 46 sets an output signal high, based on an AND logical operation of a signal PDE determining an operation mode of the CMOS logic circuit and the control signal DET2 from well potential detecting circuit 45. Ring oscillator 47 is activated when high signal is input, and outputs a periodic clock. Charge pump circuit 48 is connected to the N well, and injects positive charges into the N well in accordance with a prescribed mode, when the clock is input. Discharging circuit 70 releases positive charges from the N well in response to control signal DET3 from well potential detecting circuit 45 and signal PDE, to lower Vbn.

Referring to FIG. 14, P well potential control portion 2e includes a well potential detecting circuit 45a monitoring Vbp, an AND circuit 46a, a ring oscillator 47a activated by an output signal of the AND circuit 46a, a charge pump circuit 48a activated by an output signal of ring oscillator 47a, and a charge injection circuit 49 for raising Vbp.

Well potential detecting circuit 45a sets control signals DET0 and DET1 from low to high, in response to change of Vbp. AND circuit 46a sets an output signal high, based on the AND logical operation of signal PDE and control signal DET0 from well potential detecting circuit 45a. Ring oscillator 47a is activated when high signal is input, and outputs a periodic clock. Charge pump circuit 48a is connected to the P well, and “pumps out” charges in the P well when the clock is input, in accordance with the prescribed mode. Charge injection circuit 49 injects positive charges into the P well in response to control signal DET1 from well potential detecting circuit 45a and signal PDE, to raise Vbp.

Referring to FIG. 15, charge injection circuit 49 includes an NOR circuit 50 receiving control signal DET1 from well potential detecting circuit 45a and signal PDE; and a P channel MOS transistor 51 and an N channel MOS transistor 52 connected in series between an output node N1 of NOR circuit 50 and the P well.

In the conventional VT model, the CMOS logic circuit constituted by P channel MOS transistor 4 and N channel MOS transistor 5 in FIG. 12 operates in two modes, that is, a stand-by mode and an active mode. In the stand-by mode and the active mode, signal PDE is set high and low respectively.

In the stand-by mode, in order to reduce the off-leak current of the transistor, N well potential control portion 1e controls Vbn, and P well potential control portion 2e controls Vbp so that |Vthp| and Vthn attain high.

On the other hand, in the active mode, in order to implement high-speed operation of the transistors, N well potential control portion 1e controls Vbn, and P well potential control portion 2e controls Vbp so that |Vthp| and Vthn attain low.

FIG. 16 shows an example of a relation between the well potential and signal PDE in the stand-by mode and the active mode of the VT model. Periods 1, 3 represent the active mode, while period 2 represents the standby mode. In the stand-by mode, a target potential of Vbn is VbnH, and the target potential of Vbp is VbpD. In the active mode, the target potential of Vbn is VbnL, and the target potential of Vbp is VbpS. Here, VbnL may be any voltage not lower than ground voltage GND, and VbpS not higher than ground voltage GND.

Next, an operation of N well potential control portion 1e will be described. Referring again to FIG. 13, N well potential control portion 1e operates in response to a change in N well potential Vbn. In the stand-by mode, signal PDE is set high. Well potential detecting circuit 45 sets signal DET2 high if Vbn is lower than VbnH. Here, AND circuit 46 sets an output signal high, based on the AND logical operation of signals DET2 and PDE, and activates ring oscillator 47. With the activation of ring oscillator 47, charge pump circuit 48 operates to raise Vbn until Vbn attains VbnH.

In the active mode, signal PDE is set low. Well potential detecting circuit 45 sets signal DET3 low if Vbn is higher than VbnL. Discharging circuit 70 operates when signals PDE and DET3 that are input are both set low, and releases positive charges in the N well, to lower Vbn until Vbn attains VbnL.

Referring again to FIG. 14, P well potential control portion 2e operates in response to a change in P well potential Vbp. In the stand-by mode, signal PDE is set high. Well potential detecting circuit 45a sets signal DET0 high if Vbp is higher than VbpD. AND circuit 46a sets an output signal high, based on the AND logical operation of signals DET0 and PDE, and activates ring oscillator 47a. With the activation of ring oscillator 47a, charge pump circuit 48a operates to lower Vbp until Vbp attains VbpD.

In the active mode, signal PDE is set low. Well potential detecting circuit 45a sets signal DET1 low if Vbp is lower than VbpS. Charge injection circuit 49 operates when signals PDE and DET1 that are input are both set low, and injects positive charges into the P well, to raise Vbp until Vbp attains VbpS.

Referring again to FIG. 16, an operation of P well potential control portion 2e in a transition from the stand-by mode to the active mode will be described as an example. At time t1, transition to low of signal PDE is recognized.

At this time point, as Vbp is lower than VbpS, signal DET1 is low. In charge injection circuit 49, when signals PDE and DET1 at low level are input to NOR circuit 50, the potential at node N1 attains Vcc2, which is supplied to NOR circuit 50.

Here, charges flow into the P well through P channel MOS transistor 51 and N channel MOS transistor 52, and the potential of Vbp will rise higher.

At time t2, Vbp attains the target potential VbpS. When charges are further supplied into the P well and Vbp exceeds VbpS, signal DET1 make a transition from low to high. When signal DET1 is set high, charge injection circuit 49 is inactivated, and the potential of Vbp stops rising.

As N well potential control portion 1e operates in a manner similar to P well potential control portion 2e, detailed description will not be repeated.

With these operations, in the stand-by mode, the well potential of the CMOS logic circuit is controlled such that relations of Vbn=VbnH and Vbp=VbpD are achieved. Consequently, Vthn and |Vthp| increase, and the off-leak current of the CMOS logic circuit can be reduced. On the other hand, in the active mode, the well potential of the CMOS logic circuit is controlled such that relations of Vbn=VbnL and Vbp=VbpS are achieved. Consequently, |Vthp| and Vthn decrease, and the high-speed operation of semiconductor device 210 can be implemented.

As described above, in semiconductor device 210 of the conventional VT model, for example, supply voltage Vcc2 used in charge injection circuit 49 for raising the potential of Vbp generally uses a potential supplied from the outside, or a potential obtained by internally lowering the former. Accordingly, if supply voltage Vcc2 is not originated from a dedicated power supply provided solely for controlling the well potential, charges from supply voltage Vcc2 are consumed in the course of the transition from the stand-by mode to the active mode. This will significantly fluctuate the level of Vcc2, and may influence operations of other circuitry during the initial stage of the active mode.

In addition, in the portable equipment, the stand-by mode and the active mode are frequently switched in order to suppress power consumption as much as possible. In the transition from the stand-by mode to the active mode, discharging circuit 70 in N well potential control portion 1e releases charges in the N well so as to lower Vbn, for example. Charge injection circuit 49 in P well potential control portion 2e, for example, in order to raise Vbp, which is a negative potential, injects charges into the P well from Vcc2, and consumes charges of supply voltage Vcc2. In contrast, in the transition from the active mode to the stand-by mode, charge pump circuit 48a operates to “pump up” charges from the P well, and the negative potential Vbp is raised. In either mode transition, charges are wasted, and lowering of power consumption is prevented.

Further, in the portable equipment, time required for switching from the stand-by mode to the active mode is desired to be as short as possible. Generally, however, parasitic resistance Rw and parasitic capacitance Cw of the P well and the N well are very high. This will prevent a quick charge movement, and time required for switching modes tends to be extended. In order to solve the problems, for example, an approach to improve current drivability by increasing channel width of P channel MOS transistor 51 and N channel MOS transistor 52 of charge injection circuit 49 is possible. However, even if an impedance from Vcc to a source of N channel MOS transistor 52 is lowered with such an approach, significant effect cannot be obtained because propagation delay inherent on the P well will determine the time period for transition from the stand-by mode to the active mode.

### SUMMARY OF THE INVENTION

An object of the present invention is to provide a semiconductor device, in which, in a transition from a stand-by mode to an active mode, excess charges in an N well are moved into a P well to reduce power consumption for controlling a well potential, without wasting charges, and time for transition from the stand-by mode to the active mode is shortened.

In summary, according to the present invention, a semiconductor device having a plurality of modes includes a CMOS logic circuit, a first potential control portion, a second potential control portion, and a charge transfer portion. The CMOS logic circuit has a plurality of transistors formed on an N well and a P well respectively. The first potential control portion, in each mode, controls a potential of the N well to a first target potential preset for the plurality of modes. The second potential control portion, in each mode, controls a potential of the P well to a second target potential preset for the plurality of modes. The charge transfer portion electrically connects the N well to the P well, in response to a prescribed mode transition between the plurality of modes.

Therefore, a main advantage of the present invention is that, excess charges in the N well can be moved into the undercharged P well by monitoring the potentials of the N well and the P well in the CMOS logic circuit in response to the mode transition. Consequently, a semiconductor device capable of lowering power consumption without wasting charges can be implemented.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a configuration of a semiconductor device in a first embodiment of the present invention.

FIG. 2 is a cross-sectional view of the semiconductor device in the first embodiment of the present invention.

FIG. 3 shows a detailed configuration of the semiconductor device in the first embodiment of the present invention.

FIG. 4 shows a first example of a configuration of a level conversion circuit 24.

FIG. 5 shows a second example of the configuration of level conversion circuit 24.

FIG. 6 is a conceptual view illustrating a relation of potentials of Vbn and Vbp with states of signals DETN0, DETN1, DETP0 and DETP1.

FIG. 7 shows a configuration of a semiconductor device according to a variation of the first embodiment of the present invention.

FIG. 8 shows a detailed configuration of a semiconductor device in a second embodiment of the present invention.

FIG. 9 is an operational waveform diagram showing an operation for controlling a well potential in the semiconductor device in the second embodiment of the present invention.

FIG. 10 shows a configuration of a discharging circuit 37 and a charge injection circuit 39.

FIG. 11 shows a configuration of a semiconductor device in a third embodiment of the present invention.

FIG. 12 shows a configuration of a conventional semiconductor device.

FIG. 13 shows a configuration of a conventional N well potential control portion 1e.

FIG. 14 shows a configuration of a conventional P well potential control portion 2e.

FIG. 15 is a circuit diagram of a charge injection circuit 49.

FIG. 16 shows a relation of a well potential with a signal PDE.

### DESCRIPTION OF THE PREFERRED EMBODIMENTS

In the following, embodiments of the present invention will be described in detail with reference to the figures. It is noted that the same reference characters refer to the same or corresponding components in the figures.

(First Embodiment)

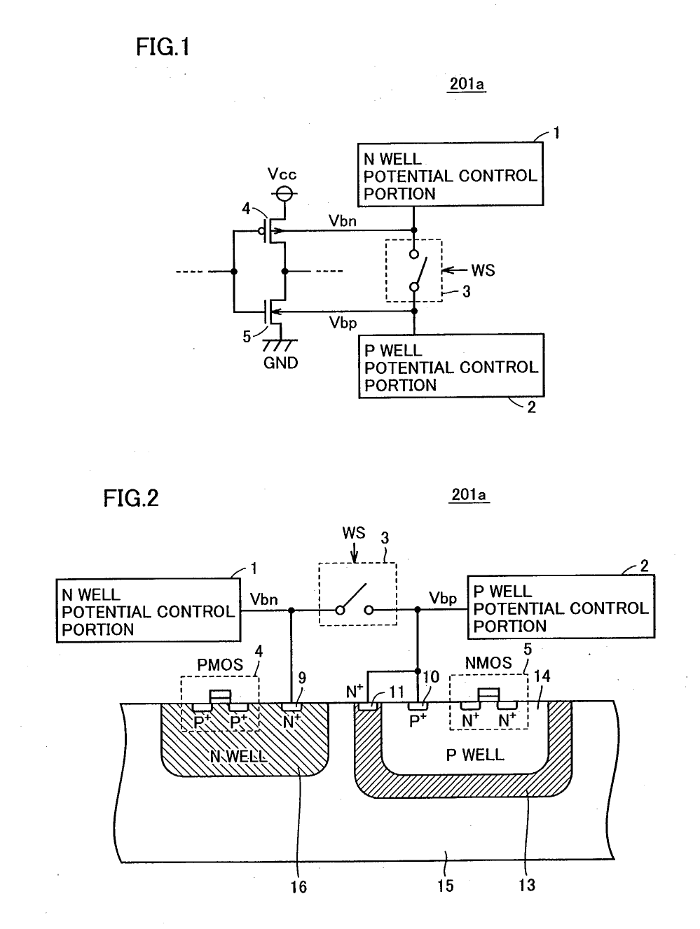

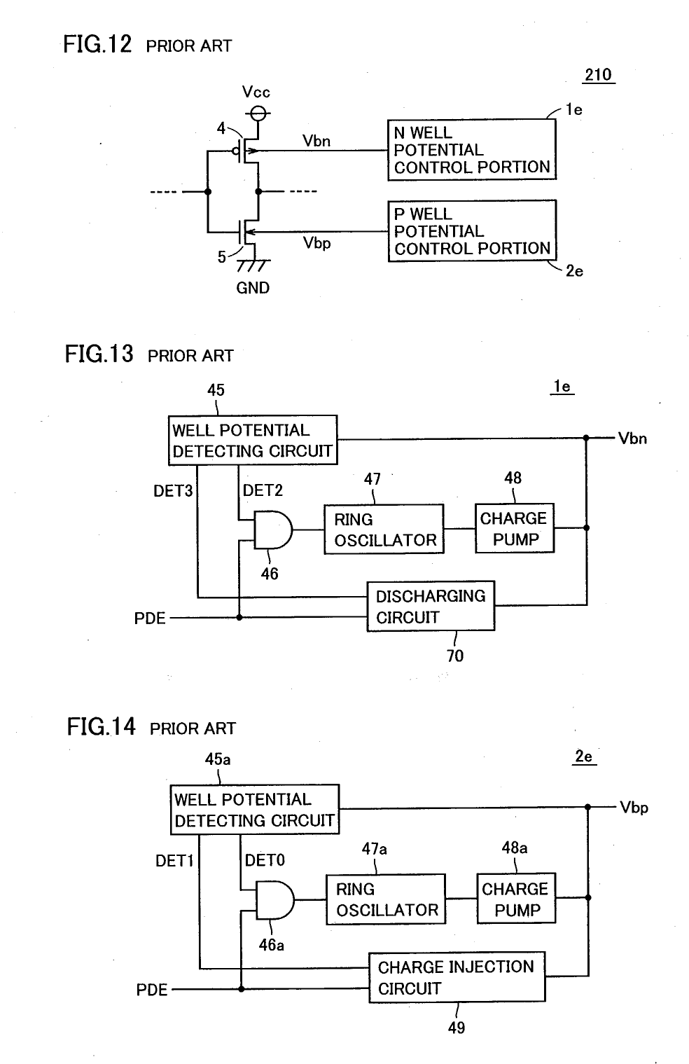

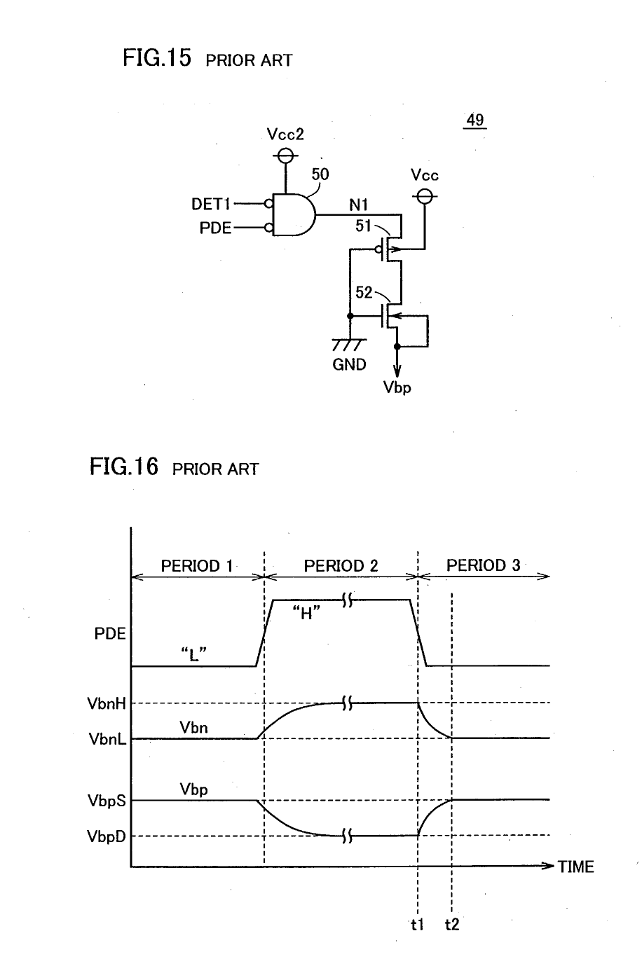

Referring to FIG. 1, a semiconductor device 201a according to a first embodiment of the present invention is different from semiconductor device 210 using the VT model in accordance with a conventional technique shown in FIG. 12, in that it includes an N well potential control portion 1 and a P well potential control portion 2, instead of N well potential control portion 1e and P well potential control portion 2e respectively, and that it further includes a switch 3.

N well potential control portion 1 is different from N well potential control portion 1e in that it does not include a discharging circuit releasing positive charges in the N well. N well potential control portion 1, however, is similar to N well potential control portion 1e in that it controls an N well potential to a target potential preset for a plurality of modes (stand-by mode/active mode). P well potential control portion 2 is different from P well potential control portion 2e in that it does not include a charge injection circuit injecting positive charges into the P well. P well potential control portion 2 is similar to P well potential control portion 2e in that it controls a P well potential to a target potential preset for the plurality of modes (stand-by mode/active mode). Switch 3 is provided between N well potential control portion 1 and P well potential control portion 2, and electrically connects the N well to the P well in response to a transition from the stand-by mode to the active mode.

FIG. 2 is a cross-sectional view of semiconductor device 201a according to the first embodiment of the present invention.

Referring to FIG. 2, semiconductor device 201a according to the first embodiment includes a P-type substrate 15, N well potential control portion 1, P well potential control portion 2, and switch 3 provided between N well potential control portion 1 and P well potential control portion 2. P-type substrate 15 includes an N well 16 formed on a surface layer, a P well 14, and a bottom N well 13 surrounding P well 14 and formed so as to electrically isolate P-type substrate 15. N well 16 has an N well connection portion 9 formed on the surface. P well 14 has a P well connection portion 10 formed on the surface.

P channel MOS transistor 4 is formed on N well 16. N well potential control portion 1 is connected to N well 16 by N well connection portion 9. N channel MOS transistor 5 is formed on P well 14. P well potential control portion 2 is connected to P well 14 by P well connection portion 10.

An N well connection portion 11 is formed on the surface of bottom N well 13. N well connection portion 11 is connected to P well potential control portion 2 and P well connection portion 10. Though the potential of bottom N well 13 is set to Vbp, which is the same as that of P well connection portion 10, it may be set to a different independent potential which is normally at Vbp or higher.

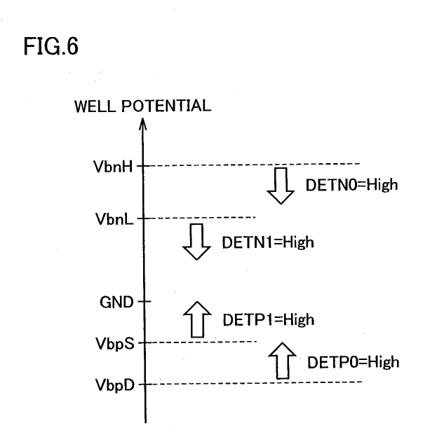

FIG. 6 shows an example of a relation of the potentials of Vbn and Vbp with states of signals DETN0, DETN1, DETP0 and DETP1. As described above, in this illustration, N well potential VbnL has only to be set to ground voltage GND or higher while P well potential VbpS has only to be set to ground voltage GND or lower. If Vbn reaches a potential not higher than VbnH, signal DETN0 makes a transition from low to high. If Vbn reaches a potential not higher than VbnL, signal DETN1 makes a transition from low to high. If Vbp reaches a potential not lower than VbpD, signal DETP0 makes a transition from low to high. If Vbp reaches a potential not lower than VbpS, signal DETP1 makes a transition from low to high.

Next, an operation of semiconductor device 201a in a transition from the stand-by mode to the active mode will briefly be described. Referring again to FIG. 2, after the transition to the active mode, control signal WS attains high and switch 3 turns on during a period in which Vbn is higher than VbnL, that is, excess charges are present in N well 16 having the P channel MOS transistor formed therein. As a result, excess charges are fed to P well 14 having the N channel MOS transistor formed therein, to lower Vbn and raise Vbp. Thus, electrical power consumed to achieve a prescribed value for the well potential can be suppressed.

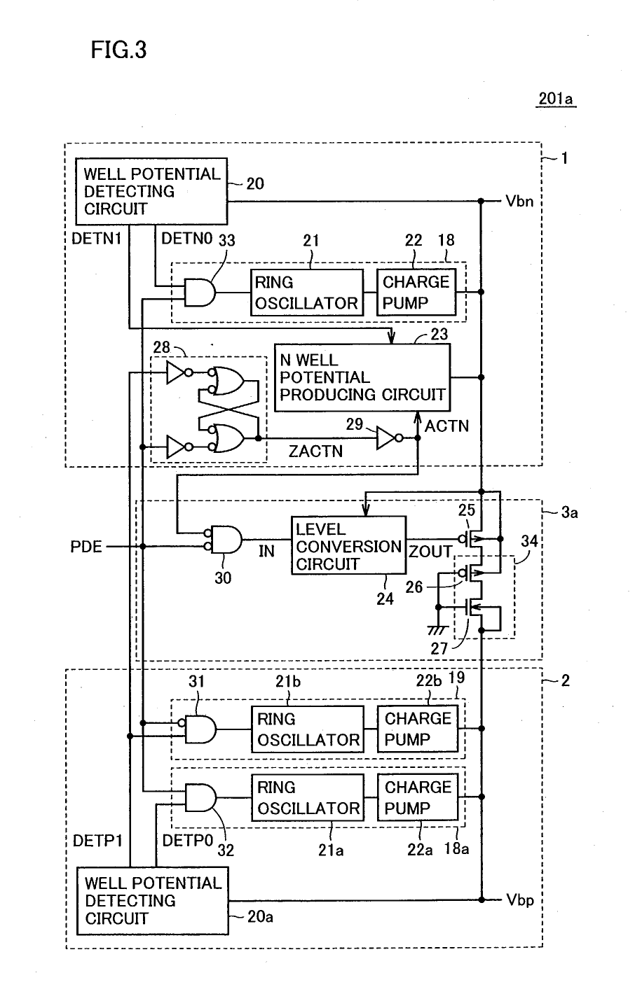

FIG. 3 shows a detailed configuration of N well potential control portion 1 and P well potential control portion 2 in semiconductor device 201a shown in FIGS. 1 and 2 according to the first embodiment of the present invention. FIG. 3 shows a configuration of semiconductor device 201a adapted to an example in which an amount of excess charges in the N well is equal to or larger than that required in the P well in a transition from the stand-by mode to the active mode. Here, equations (1) and (2) shown below hold.

Cwn×(VbnH−VbnL)=Cwp×(VbpS−VbpD) (1)

Cwn×(VbnH−VbnL)>Cwp×(VbpS−VbpD) (2)

In equations (1) and (2), Cwp represents an average parasitic capacitance in the P well, and Cwn represents an average parasitic capacitance in the N well.

Equation (1) holds when an amount of excess charges to be released from the N well is equal to that required in the P well. Equation (2) holds when an amount of excess charges in the N well is larger than that required in the P well.

Referring to FIG. 3, semiconductor device 201a according to the first embodiment includes N well potential control portion 1, P well potential control portion 2, and a charge transfer portion 3a acting in a manner similar to switch 3 and provided between N well potential control portion 1 and P well potential control portion 2.

N well potential control portion 1 includes a well potential detecting circuit 20, a voltage generating portion 18 supplying charges to the N well in the stand-by mode, an RS flip-flop circuit 28, an inverting circuit 29 inverting an output signal from RS flip-flop circuit 28 to output signal ACTN, and an N well potential producing circuit 23 releasing charges in the N well or supplying charges to the same in the active mode.

Well potential detecting circuit 20 connected to the N well having the P channel MOS transistor formed therein always monitors Vbn, and sets control signals DETN1 and DETN0 from low to high in response to change of Vbn. Voltage generating portion 18 is connected to that N well, and supplies charges to that N well in response to signals DETN0 and PDE. Control signal DETP1 from a well potential detecting circuit 20a in P well potential control portion 2 and signal PDE are input to RS flip-flop circuit 28. N well potential producing circuit 23 connected to the N well is activated when signal ACTN input from inverting circuit 29 is set high, and monitors signal DETN1 from well potential detecting circuit 20. Then, N well potential producing circuit 23 acts to lower the potential of Vbn by releasing charges in the N well when Vbn is higher than VbnL. In addition, N well potential producing circuit 23 injects charges into the N well to raise the potential of Vbn when Vbn is lower than VbnL. In other words, it operates to maintain the relation, Vbn=VbnL.

Voltage generating portion 18 includes an AND circuit 33 to which signals PDE and DETN0 are input, a ring oscillator 21 activated when an output signal from AND circuit 33 is set high and outputting a periodic clock, and a charge pump circuit 22 connected between ring oscillator 21 and the N well and supplying charges to the N well when that clock is input. Voltage generating portion 18 operates only in the stand-by mode.

P well potential control portion 2 includes a well potential detecting circuit 20a, a voltage generating portion 18a releasing charges to generate a negative voltage in the stand-by mode, and a voltage generating portion 19 releasing charges to generate a negative voltage in the active mode.

Well potential detecting circuit 20a connected to the P well having the N channel MOS transistor formed therein always monitors Vbp, and outputs control signals DETP1 and DETP0 in response to change of Vbp. Voltage generating portion 18a has the same configuration as voltage generating portion 18, and operates in the stand-by mode. Voltage generating portion 18a releases charges in the P well in response to signals DETP0 and PDE, and generates a negative voltage in the P well. Voltage generating portion 19 also has the same configuration as voltage generating portion 18, and operates in the active mode. Voltage generating portion 19 releases charges in the P well in response to signals DETP1 and PDE, and generates the negative voltage in the P well.

Charge transfer portion 3a includes an NOR circuit 30; a level conversion circuit 24 increasing the amplitude of an output signal from NOR circuit 30 to output signal ZOUT; and a P channel MOS transistor 25 and a resistance circuit 34 that are connected in series between N well potential control portion 1 and P well potential control portion 2 and operate as a switching circuit in response to a transition from the stand-by mode to the active mode. Resistance circuit 34 has a P channel MOS transistor 26 and an N channel MOS transistor 27 that are connected in series. P channel MOS transistor 26 and N channel MOS transistor 27 inject excess charges from the N well, delivered via P channel MOS transistor 25, into the P well, with concurrent lowering of the voltage.

Not one but three transistors which act to transfer charges are connected in series, and thus voltage applied to one transistor is lowered by dividing resistance. Therefore, problems such as lower reliability due to hot carrier, or punchthrough can be avoided.

NOR circuit 30 sets signal IN high when output signal ACTN from inverting circuit 29 in N well potential control portion 1 and signal PDE are both low. P channel MOS transistor 25, P channel MOS transistor 26 and N channel MOS transistor 27 that are connected in series electrically connect the N well to the P well so that charges can move between N well potential control portion 1 and P well potential control portion 2, when signal ZOUT is input to P channel MOS transistor 25.

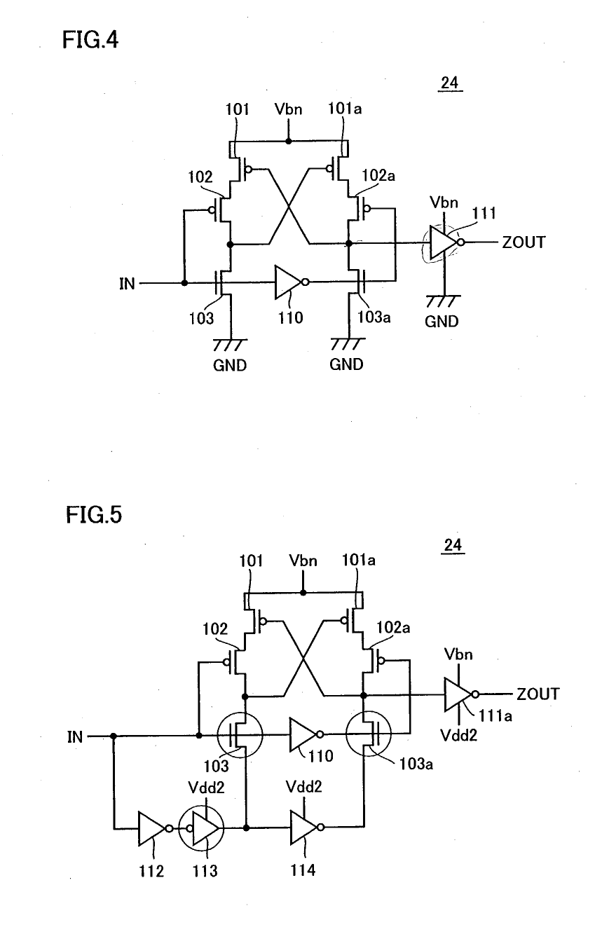

FIG. 4 shows an example of a first configuration of level conversion circuit 24. Level conversion circuit 24 has a P channel MOS transistor 101, a P channel MOS transistor 102 and an N channel MOS transistor 103 that are connected in series between operation voltage Vbn and ground voltage GND; a P channel MOS transistor 101a, a P channel MOS transistor 102a and an N channel MOS transistor 103a that are connected in series between operation voltage Vbn and ground voltage GND; an inverting circuit 110; and an inverting circuit 111. In this configuration, between Vbn and internal supply voltage Vcc used in a peripheral circuit (NOR circuit 30, for example), the relation of Vbn>Vcc is achieved.

The gate of P channel MOS transistor 101 is connected to a connection node of P channel MOS transistor 102a and N channel MOS transistor 103a. The gate of P channel MOS transistor 101a is connected to a connection node of P channel MOS transistor 102 and N channel MOS transistor 103. Signal IN is directly input to the gates of P channel MOS transistor 102 and N channel MOS transistor 103. Inverting circuit 110 inverts IN, and input the same to each gate of N channel MOS transistor 103 and N channel MOS transistor 103a.

Inverting circuit 111 receives a signal from a connection node of P channel MOS transistor 102a and N channel MOS transistor 103a as an input, and inverts the voltage level thereof, to generate signal ZOUT. Signal ZOUT has a high voltage of Vbn and low voltage of ground voltage GND. In other words, ZOUT (GND−Vbn) is a signal obtained by increasing the amplitude of IN (GND−Vcc). Consequently, high output signal ZOUT can turn off P channel MOS transistor 25.

In this circuit configuration, however, the voltage (voltage between the gate and the source) applied to a gate oxide film of the transistor when P channel MOS transistor 25 turns on (that is, when output signal ZOUT is at low level) becomes large, and this may lower operational reliability. As a solution, it is possible to make thicker the gate oxide film of P channel MOS transistor 25 or to raise low voltage of signal ZOUT to a level slightly higher than ground voltage GND.

FIG. 5 shows an example of a second configuration of level conversion circuit 24, in which, in order to ensure further reliability of the gate oxide film, a low voltage of signal ZOUT is set slightly higher than ground voltage GND.

Level conversion circuit 24 in FIG. 5 is different from level conversion circuit 24 according to the first example shown in FIG. 4, in that sources of N channel MOS transistor 103 and N channel MOS transistor 103a are not directly connected to ground voltage GND, and that the level conversion circuit 24 further includes inverting circuits 112 to 114. Inverting circuit 112 inputs a signal obtained by inverting signal IN to inverting circuit 113. Inverting circuit 113, further setting Vdd2 to high level, inverts a signal output from inverting circuit 112, and inputs the signal to the source of N channel MOS transistor 103 and inverting circuit 114. Inverting circuit 114, further setting Vdd2 to high level, inverts a signal from a connection node of the source of N channel MOS transistor 103 and inverting circuit 113, and inputs the signal to the source of N channel MOS transistor 103a.

In addition, inverting circuit 111 of level conversion circuit 24 in FIG. 4 is connected between Vbn and ground voltage GND, while an inverting circuit 111a of level conversion circuit 24 in FIG. 5 is connected between Vbn and Vdd2 of a potential slightly higher than ground voltage GND. As other configurations are the same as in level conversion circuit 24 in the first configuration example shown in FIG. 4, detailed description will not repeated.

Here, it is assumed that a threshold voltage of the P channel MOS transistor constituting inverting circuit 113 is Vthp0, and a threshold voltage of N channel MOS transistors 103, 103a is Vthn0. If the following equations hold, that is,

Vdd2>Vthp0 (3)

and

Vcc>Vdd2+Vthn0 (4),

low level of output signal ZOUT is Vdd2. Thus, the amplitude of output signal ZOUT can be made smaller. Accordingly, maximum voltage applied to the gate oxide film of P channel MOS transistor 25 in charge transfer portion 3a can be lowered by Vdd2, and operational reliability can be ensured without thickening the gate oxide film.

Next, an operation of semiconductor device 201a will be described, in a transition from the stand-by mode to the active mode when an amount of excess charges in the N well is equal to or larger than that required in the P well.

Referring again to FIG. 3, charge transfer portion 3a is activated for a certain period immediately after a transition from the stand-by mode to the active mode. In order to feed the excess charges to the P well portion where the N channel MOS transistor is formed, N well potential control portion 1 is electrically connected to P well potential control portion 2. When injection of charges into the P well is completed, charge transfer portion 3a stops transferring charges, and N well potential control portion 1 is electrically isolated from P well potential control portion 2. Here, if equation (2) holds and there still remain charges to be released in the N well, N well potential producing circuit 23 in N well potential control portion 1 releases the excess charges in the N well so that Vbn achieves a balanced state.

In N well potential control portion 1, in the stand-by mode, when Vbn is at a potential lower than VbnH, signal DETN0 is set high. Then, high signals DETN0 and PDE are input to AND circuit 33, which activates ring oscillator 21. Ring oscillator 21 outputs a periodic clock to charge pump circuit 22. Charge pump circuit 22 sets Vbn to VbnH, upon receiving the clock from ring oscillator 21.

In P well potential control portion 2, in the stand-by mode, when Vbp is at a potential higher than VbpD, signal DETP0 is set high. Then, high signals DETP0 and PDE are input to an AND circuit 32, which activates a ring oscillator 21a. Ring oscillator 21a outputs a periodic clock to a charge pump circuit 22a. Charge pump circuit 22a sets Vbp to VbpD, upon receiving the clock from ring oscillator 21a.

In the stand-by mode, high signal PDE is input to NOR circuit 30, and signal IN is set low. Therefore, charge transfer portion 3a is not activated.

In charge transfer portion 3a, signal PDE is set from high to low by the transition from stand-by mode to the active mode. Here, output signal ZACTN of RS flip-flop circuit 28 remains high until signal DETP1 is set high. Therefore, NOR circuit 30, to which an inverted signal of high signal ZACTN as well as low signal PDE are input, sets signal IN high until Vbp=VbpS is achieved and charging to the P well is completed. The level conversion circuit converts the potential of signal IN, and outputs signal ZOUT to a gate of P channel MOS transistor 25. Here, P channel MOS transistor 25, P channel MOS transistor 26 and N channel MOS transistor 27 that are connected in series electrically connect the N well to the P well so that charges can move from N well potential control portion 1 to P well potential control portion 2.

When Vbp=VbpS is achieved and signal DETP1 is set from low to high in response to completion of charging to the P well, signal ACTN input to NOR circuit 30 is set high. When high signal ACTN is input to NOR circuit 30, charge transfer portion 3a is inactivated, N well potential control portion 1 is electrically isolated from P well potential control portion 2, and movement of the charges is completed.

In N well potential control portion 1, signal PDE is set from high to low after the transition from the stand-by mode to the active mode. A potential of the P well achieves Vbp=VbpS, and output signal ZACTN of RS flip-flop circuit 28 remains high until signal DETP1 is set high. Therefore, charge transfer portion 3a is activated, and excess charges in the N well will move to the undercharged P well.

When equation (1) holds, that is, an amount of excess charges in the N well is equal to that required in the P well, a time period until Vbn=VbnL is achieved after the transition from the stand-by mode to the active mode is equal to that until Vbp=VbpS is achieved. In such a case, discharge of the N well and charging to the P well are completed at the same time. Therefore, since relations of Vbn=VbnL and Vbp=VbpS are achieved at the same time, charge transfer portion 3a is also inactivated at that time.

When equation (2) holds, that is, an amount of excess charges in the N well is larger than that required in the P well, a time period until Vbn=VbnL is achieved after the transition from the stand-by mode to the active mode is longer than that until Vbp=VbpS is achieved. Therefore, charging to the P well is completed before discharge ends.

Here, since there still remain charges to be released in the N well, N well potential producing circuit 23 releasing charges in the N well to lower the potential of Vbn should be activated. Therefore, charging to the P well is completed before discharge ends, and Vbp=VbpS is achieved. Then, signal DETP1 is set from low to high, and signal ZACTN is set from high to low. Therefore, signal ACTN is set from low to high. When signal ACTN is set high, charge transfer portion 3a is inactivated, and charge transfer stops. When signal ACTN is set high, however, N well potential producing circuit 23 is activated to start releasing charges in the N well. Therefore, the potential of Vbn is further lowered. In addition, N well potential producing circuit 23, when activated, also refers to signal DETN1.

When Vbn=VbnL is achieved, signal DETN 1 is set from low to high. Thereafter, N well potential producing circuit 23 operates with reference to signal DETN1. If Vbn is lower than VbnL, N well potential producing circuit 23 supplies charges to the N well until Vbn=VbnL is achieved. In other words, N well potential producing circuit 23 operates so that Vbn-VbnL is achieved.

In P well potential control portion 2, after the transition from the stand-by mode to the active mode, charging to the P well is completed, and Vbp=VbpS is achieved. Then, signal DETP1 is set from low to high. Here, high signal ACTN is input to NOR circuit 30 in charge transfer portion 3a. Therefore, charge transfer portion 3a is inactivated, and N well potential control portion 1 is electrically isolated from P well potential control portion 2. A logic circuit 31 activates a ring oscillator 21b when low signal PDE and high signal DETP1 are input.

Ring oscillator 21b outputs a periodic clock to a charge pump circuit 22b. Upon receiving the clock from ring oscillator 21b, charge pump circuit 22b releases charges in the P well as needed so that Vbp maintains VbpS.

As described above, in semiconductor device 201a according to the first embodiment, adapted to an example in which an amount of excess charges in the N well is equal to or larger than that required in the P well, the excess charges in the N well are moved into the P well in a transition from the stand-by mode to the active mode. Thus, power consumption for controlling the well potential can be reduced, without wasting the charges.

(Variation of First Embodiment)

Next, according to the first embodiment of the present invention, a configuration of a semiconductor device 201b adapted to an example, in which an amount of excess charges in the N well is smaller than that required in the P well in a transition from the stand-by mode to the active mode, will be described. Here, equation (5) below is achieved.

Cwn×(VbnH−VbnL)<Cwp×(VbpS−VbpD) (5)

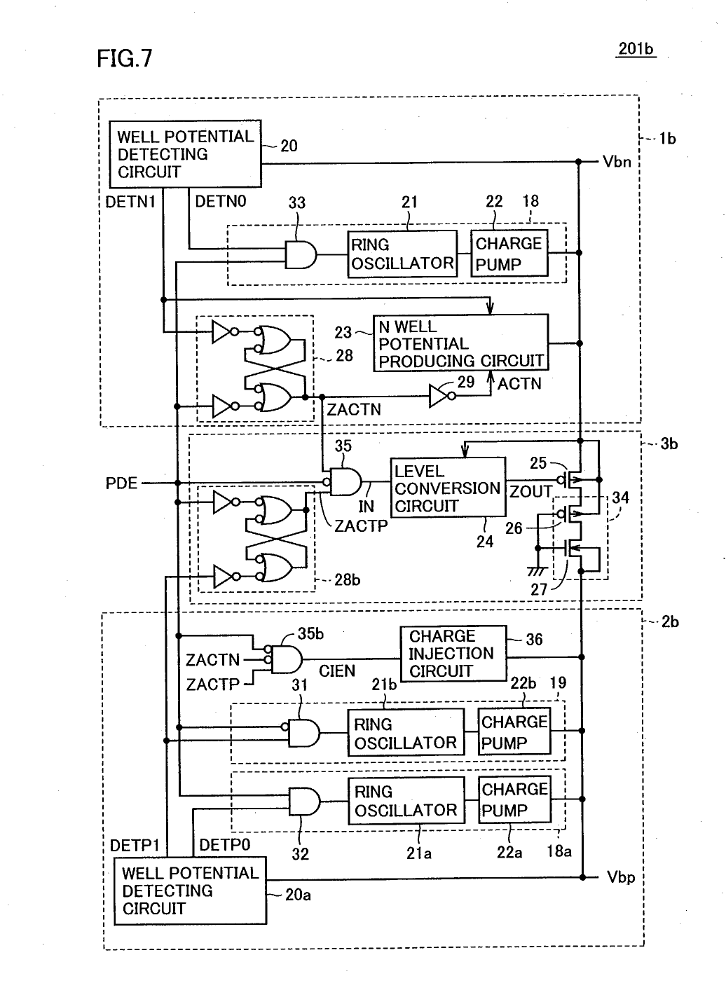

Referring to FIG. 7, semiconductor device 201b according to a variation of the first embodiment is different from semiconductor device 201a in that it includes an N well potential control portion 1b, a P well potential control portion 2b and a charge transfer portion 3b, instead of N well potential control portion 1, P well potential control portion 2 and charge transfer portion 3a respectively.

N well potential control portion 1b is different from N well potential control portion 1 in that signal DETN1 detecting a potential of Vbn, instead of signal DETP1 detecting a potential of Vbp is provided as an input signal to RS flip-flop circuit 28. In this configuration, N well potential control portion 1b is controlled irrespective of the potential of Vbp. Since other configurations are the same as in N well potential control portion 1 shown in FIG. 3, detailed description will not be repeated.

P well potential control portion 2b is different from P well potential control portion 2 in that it further includes a logic circuit 35b, to which signals PDE, ZACTN and ZACTP are input, as well as a charge injection circuit 36 activated by an output signal CIEN of logic circuit 35b. As signals ZACTN and ZACTP are input to logic circuit 35b, charge injection circuit 36 receiving output signal CIEN from logic circuit 35b is activated in accordance with the potentials of Vbn and Vbp in the active mode. Since other configurations are the same as in P well potential control portion 2 shown in FIG. 3, detailed description will not be repeated.

Charge transfer portion 3b is different from charge transfer portion 3a in that it includes a logic circuit 35 instead of NOR circuit 30 and further includes an RS flip-flop circuit 28b. Signals PDE and DETP1 are input to RS flip-flop circuit 28b, which provides output signal ZACTP to logic circuit 35. Logic circuit 35 sets output signal IN high or low in accordance with signals PDE, ZACTP and ZACTN. In other words, charge transfer portion 3b is activated by signals DETP1 and DETN1. Since other configurations are the same as in charge transfer portion 3a shown in FIG. 3, detailed description will not be repeated.

Next, an operation of semiconductor device 201b in the transition from the stand-by mode to the active mode will be described. Referring again to FIG. 7, charge transfer portion 3b is activated for a certain period immediately after the transition from the stand-by mode to the active mode. In order to feed the excess charges to the P well portion having the N channel MOS transistor formed therein, N well potential control portion 1b is electrically connectd to P well potential control portion 2b. When release of the excess charges in the N well is completed, charge transfer portion 3b stops transferring charges, and N well potential control portion 1b is electrically isolated from P well potential control portion 2b.

Here, equation (5) holds, which means that the P well is still undercharged even after the excess charges are released from the N well. Then, charge injection circuit 36 injects charges required in the P well into the same so that Vbp achieves a balanced state.

N well potential control portion 1b operates in a manner similar to N well potential control portion 1 in the stand-by mode, and charge pump circuit 22 sets Vbn to VbnH. P well potential control portion 2b operates in a manner similar to P well potential control portion 2 in the stand-by mode, and charge pump circuit 22a sets Vbp to VbpD. In the stand-by mode, charge transfer portion 3b is not activated because high signal PDE is input to logic circuit 35 and signal IN is set low.

In charge transfer portion 3b, signal PDE is set from high to low by the transition from stand-by mode to the active mode. Here, output signal ZACTN of RS flip-flop circuit 28 remains high until Vbn=VbnL is achieved and signal DETN1 is set high. In addition, output signal ZACTP of RS flip-flop circuit 28b remains high until Vbp=VbpS is achieved and signal DETP1 is set high. Therefore, logic circuit 35 to which low signal PDE as well as high signals ZACTN and ZACTP are input is activated and signal IN is set high until relations of Vbn=VbnL and Vbp-VbpS are achieved and release of excess charges in the N well and charging to the P well are completed. Since subsequent operations are the same as in charge transfer portion 3a of semiconductor device 201a, detailed description will not be repeated.

In N well potential control portion 1b, in the active mode, after signal PDE is set from high to low, Vbn=VbnL is achieved, and signal DETN1 is set from low to high. Output signal ZACTN of RS flip-flop circuit 28 to which high signal DETN1 is input is set from high to low. Output signal ACTN of inverting circuit 29 is set high, and activates N well potential producing circuit 23. Thereafter, even when charge transfer portion 3b is inactivated and N well potential control portion 1b is electrically isolated from P well potential control portion 2b, N well potential producing circuit 23 will operate such that Vbn maintains positive potential VbnL. In other words, even when N well is overcharged after the transition to the active mode, in N well potential producing circuit 23, well potential detecting circuit 20 always monitors the potential of Vbn. Thus, N well potential producing circuit 23 functions to keep the potential of Vbn at a constant level by releasing the excessive charges.

In P well potential control portion 2b, after the transition from the stand-by mode to the active mode and before charging to the P well is completed and Vbp=VbpS is achieved, charge transfer portion 3b is inactivated. This is because equation (5) holds and an amount of excess charges in the N well is smaller than that required in the P well.

Therefore, after the transition from the stand-by mode to the active mode, initially in N well potential control portion 1b, Vbn=VbnL is achieved, and signal DETN1 is set from low to high. When high signal DETN1 is input to RS flip-flop circuit 28, output signal ZACTN is set low. When low signal ZACTN is input to logic circuit 35 in charge transfer portion 3b, charge transfer portion 3b is inactivated. Consequently, N well potential control portion 1b is electrically isolated from P well potential control portion 2b, and charge transfer is stopped.

Thereafter, in P well potential control portion 2b, low signals PDE, ZACTN and high signal ZACTP are input to logic circuit 35b. Accordingly, signal CIEN is set from low to high, and charge injection circuit 36 is activated. Charge injection circuit 36 injects charges into the P well until Vbp=VbpS is achieved.

When Vbp=VbpS is achieved, signal DETP1 is set from low to high, and output signal ZACTP of RS flip-flop circuit 28b in charge transfer portion 3b is set low. Accordingly, logic circuit 35b to which low signal ZACTP is input is inactivated, and charge injection circuit 36 stops operating.

At the same time, logic circuit 31 to which low signal PDE and high signal DETP1 are input activates ring oscillator 21b. Ring oscillator 21b outputs a periodic clock to charge pump circuit 22b. Upon receiving the clock from ring oscillator 21b, charge pump circuit 22b releases charges in the P well as needed so that Vbp maintains VbpS.

As described above, in semiconductor device 201b according to the variation of the first embodiment, when an amount of excess charges in the N well is smaller than that required in the P well, the excess charges in the N well are moved into the P well in a transition from the stand-by mode to the active mode. Thus, power consumption for controlling the well potential can be reduced, without wasting the charges.

(Second Embodiment)

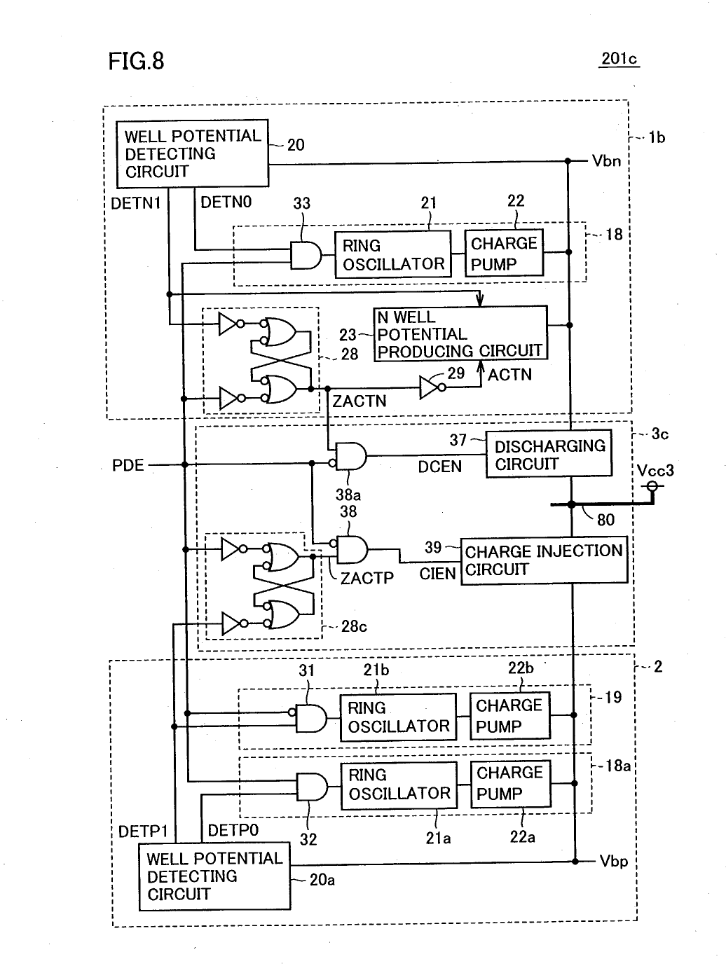

Referring to FIG. 8, a semiconductor device 201c according to a second embodiment of the present invention is different from semiconductor device 201a in FIG. 3 according to the first embodiment in that it includes N well potential control portion 1b and a charge transfer portion 3c, instead of N well potential control portion 1 and charge transfer portion 3a respectively. Since other configurations are the same as in semiconductor device 201a shown in FIG. 3, detailed description will not be repeated.

N well potential control portion 1b is different from N well potential control portion 1 in that signal DETN1 detecting the potential of Vbn, instead of DETP1 detecting the potential of Vbp, is provided as an input signal of RS flip-flop circuit 28. In this configuration, N well potential control portion 1b is controlled irrespective of the potential of Vbp. Since other configurations are the same as in N well potential control portion 1 shown in FIG. 3, detailed description will not be repeated.

Charge transfer portion 3c is different from charge transfer portion 3a in that it includes a logic circuit 38a, a discharging circuit 37 discharging the potential of the N well, and a charge injection circuit 39 injecting charges into the P well, instead of NOR circuit 30 outputting signal IN, level conversion circuit 24 as well as P channel MOS transistor 25, P channel MOS transistor 26 and N channel MOS transistor 27 that are connected in series, and in that it further includes an RS flip-flop circuit 28c to which signals PDE and DETP1 are input, a logic circuit 38 to which signal PDE and output signal ZACTP of RS flip-flop circuit 28c are input, and a power supply interconnection 80 provided between discharging circuit 37 and charge injection circuit 39.

Discharging circuit 37 and charge injection circuit 39 are connected via power supply interconnection 80. Power supply interconnection 80 supplies a prescribed voltage Vcc3 controlled in a stable manner. The prescribed voltage Vcc3 is produced and consumed within a semiconductor device, for example, and a level thereof is controlled by a potential control circuit (not shown) separately provided for dedicated use.

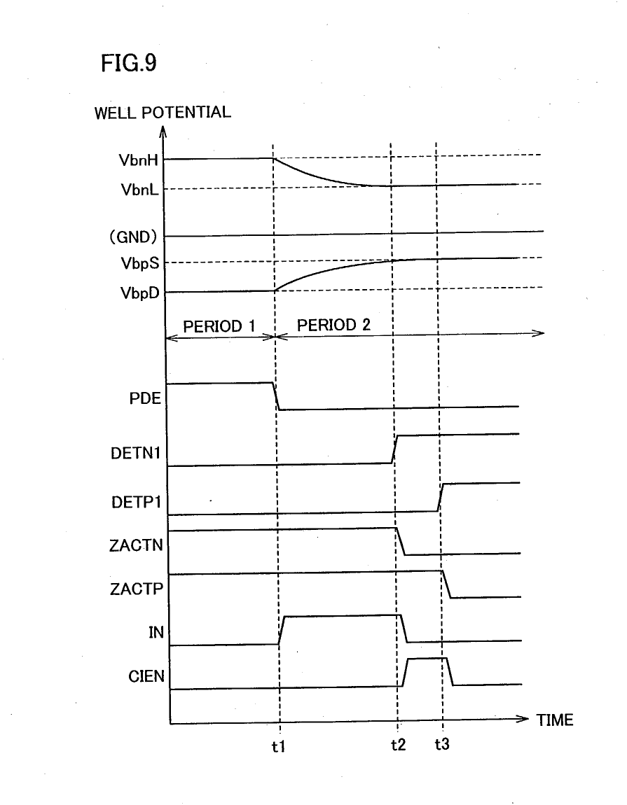

FIG. 9 shows an example of operational waveforms illustrating an operation of semiconductor device 201c according to the second embodiment, for controlling the well potential. The waveforms include those of Vbn, Vbp, and signals PDE, DETN1, DETP1, ZACTN, ZACTP, IN and CIEN. In the diagram, period 1 represents the stand-by mode while period 2 represents the active mode. Here, the P well potential VbpS may be of any voltage not higher than ground voltage GND, and VbnL not lower than ground voltage GND.

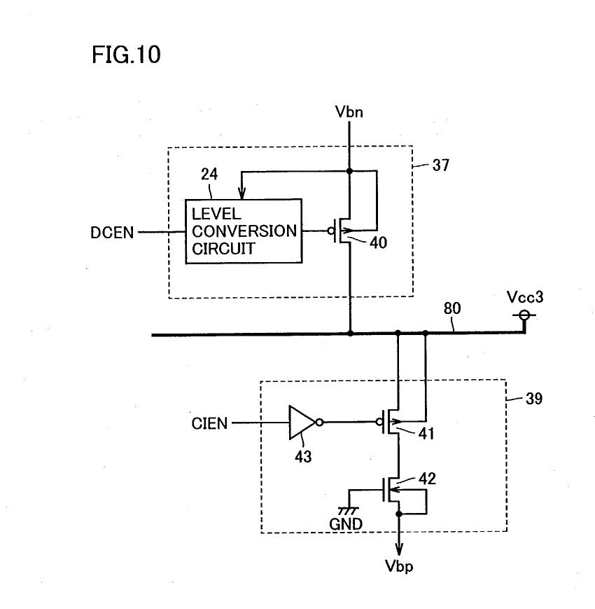

FIG. 10 shows an example of a configuration of discharging circuit 37 and charge injection circuit 39.

Discharging circuit 37 includes level conversion circuit 24 increasing the amplitude of an input signal, and a P channel MOS transistor 40.

Since level conversion circuit 24 is the same as that shown in FIG. 4 or 5, detailed description will not be repeated. Level conversion circuit 24 converts the high potential of a signal DCEN input when the N well has excess charges to the low potential at which P channel MOS transistor 40 turns on. When the P channel MOS transistor 40 turns on, the excess charges in the N well are released from the N well through the P channel MOS transistor 40 to power supply interconnection 80.

Charge injection circuit 39 includes an inverting circuit 43, and a P channel MOS transistor 41 and an N channel MOS transistor 42 that are connected in series between power supply interconnection 80 and the P well. Inverting circuit 43 sends an inverted signal of signal CIEN to a gate of P channel MOS transistor 41. The gate of N channel MOS transistor 42 is connected to ground voltage GND.

Charge injection circuit 39 is activated when the P well is undercharged and signal CIEN is set high. The high potential of signal CIEN is set low in inverting circuit 43, and turns on P channel MOS transistor 41. Then, power supply interconnection 80 is electrically connected to the P well via P channel MOS transistor 41 and N channel MOS transistor 42 which is normally on. Thereafter, charges flow into the P well from power supply interconnection 80, and charging to the P well is completed.

Next, an operation of semiconductor device 201c in the transition from the stand-by mode to the active mode will be described.

Referring again to FIG. 8, in the active mode, charge transfer portion 3c is activated when excess charges are present in the N well portion having the P channel MOS transistor formed therein, or when P well having N channel MOS transistor formed therein is undercharged. When the excess charges are present in the N well, the charges flow into power supply interconnection 80 via discharging circuit 37. When the P well is undercharged, the charges flow into the P well from power supply interconnection 80 via charge injection circuit 39.

N well potential control portion 1b operates in a manner similar to N well potential control portion 1b of semiconductor device 201b in the stand-by mode, and sets Vbn to VbnH. P well potential control portion 2 operates in a manner similar to P well potential control portion 2 of semiconductor device 201a in FIG. 3 in the stand-by mode, and sets Vbp to VbpD.

Charge transfer portion 3c is not activated because, in the stand-by mode, high signal PDE is input to logic circuits 38a, 38 and signals DCEN and CIEN are both set low.

In the active mode, as N well potential control portion 1b operates in a manner similar to N well potential control portion 1b of semiconductor device 201b described in the second embodiment, detailed description will not be repeated. In the active mode, as P well potential control portion 2 operates in a manner similar to P well potential control portion 2 of semiconductor device 201a described in the first embodiment, detailed description will not be repeated.

Referring again to FIG. 9, in charge transfer portion 3c, signal PDE is set from high to low in the transition from the stand-by mode to the active mode. Here, output signal ZACTN of RS flip-flop circuit 28 remains high until Vbn=VbnL is achieved and signal DETN1 is set high. In addition, output signal ZACTP of RS flip-flop circuit 28c remains high until Vbp=VbpS is achieved and signal DETP1 is set high.

Since Vbn is larger than VbnL (Vbn>VbnL) immediately after the transition to the active mode, signal DETN1 has been set low. Therefore, a state of RS flip-flop circuit 28 is held. In other words, output signal ZACTN remains high. Then, when low signal PDE and high signal ZACTN are input to logic circuit 38a, signal DCEN is set high. Therefore, discharging circuit 37 is activated by high signal DCEN. Here, when excess charges are present in the N well, the excess charges therein are released via discharging circuit 37 to power supply interconnection 80. When the relation of Vbn≦VbnL is achieved for the first time, ZACTN is set from high to low, and discharging circuit 37 is inactivated.

Further, since Vbp is smaller than VbpS (Vbp<VbpS) immediately after the transition to the active mode, signal DETP1 has been set low. Therefore, a state of RS flip-flop circuit 28c is held. In other words, output signal ZACTP remains high. Then, when low signal PDE and high signal ZACTP are input to logic circuit 38, signal CIEN is set high. Therefore, charge injection circuit 39 is activated by high signal CIEN. Here, when the P well is undercharged, charges required there are taken out from power supply interconnection 80 via charge injection circuit 39, to fill the P well. When the relation of Vbp≧VbpS is achieved for the first time, signal ZACTP is set from high to low, and charge injection circuit 39 is inactivated.

Power supply interconnection 80 has the excess charges input from the N well, and supplies the charges to the P well. Since it is not configured to solely consume charges from power supply potential Vcc2 as in conventional charge injection circuit 49, transitional fluctuation of the power supply potential can be suppressed. Moreover, the excess charges in the N well are concurrently released to power supply interconnection 80, from which the charges are released to the P well. Thus, power consumption can be reduced without wasting charges.

Furthermore, since power supply interconnection 80 supplies a prescribed voltage controlled in a stable manner, injection or release of some charges would be negligible. Therefore, when equation (2) or (5) holds, that is, when an amount of excess charges in the N well is either larger or smaller than that required in the P well, injection or release of charges to some extent can be managed by power supply interconnection 80. For example, even if some amount of excess charges is present in the N well, Vbn=VbnL can be achieved by releasing the charges to power supply interconnection 80. Even if charges are insufficient in the P well, the relation of Vbp=VbpS can be achieved by injecting charges from power supply interconnection 80.

In addition, if power supply interconnection 80 is provided as a thick metal wire with low impedance, slow movement of the charges can be avoided when the charges move from the N well to the P well, even if discharging circuit 37 and charge injection circuit 39 are positioned, spaced apart from each other. Therefore, the charge transfer portion 3c will have a degree of freedom for circuit arrangement higher than charge transfer portion 3a of semiconductor device 201a in FIG. 3 in the first embodiment and charge transfer portion 3b of semiconductor device 201b.

As described above, in semiconductor device 201c according to the second embodiment, when the amount of charges released from the N well is either larger or smaller than that required in the P well in the transition from the stand-by mode to the active mode, movement of the charges from the N well to the P well can be implemented with a common configuration.

In addition, the excess charges in the N well are fed to the undercharged P well, via power supply interconnection 80 supplying a prescribed voltage controlled in a stable manner. Thus, power consumption due to an operation for achieving a prescribed level of the well potential can be reduced. Further, if a thick metal wire with low impedance is used for power supply interconnection 80, the charge transfer portion can have high degree of freedom in the arrangement of circuits therein.

(Third Embodiment)

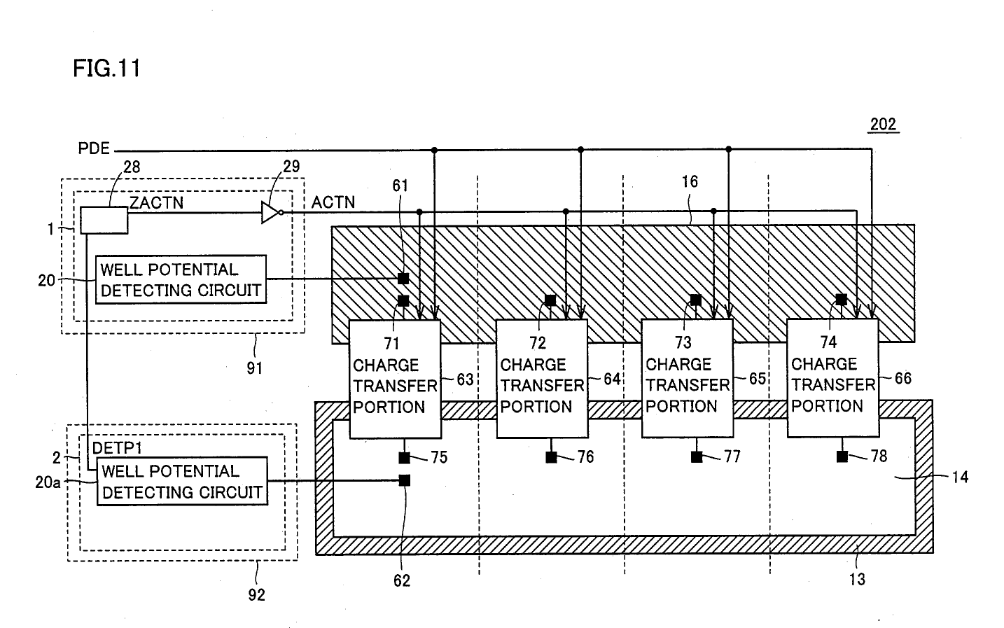

Referring to FIG. 11, a semiconductor device 202 according to a third embodiment of the present invention, which is adapted to an example in which an amount of excess charges in the N well is smaller than that required in the P well, includes N well potential control portion 1 formed on a well 91 of which potential is at constant level; P well potential control portion 2 formed on a well 92 of which potential is at constant level; N well 16 formed on the surface layer of a P-type substrate; P well 14 formed on the surface layer of the P-type substrate; a bottom N well surrounding P well 14 and formed so as to electrically isolate the P-type substrate; and charge transfer portions 63, 64, 65, 66 connecting N well connection portions. 71, 72, 73, 74 to P well connection portions 75, 76, 77, 78 respectively.

Here, it is assumed that N well 16 and P well 14 are imaginarily divided into blocks of equal area. On the N well and P well of one block provided by the imaginary division, an N well connection portion 61 connected to well potential detecting circuit 20 to detect the potential of the N well, and a P well connection portion 62 connected to well potential detecting circuit 20a to detect the potential of the P well, are formed. For each block, charge transfer portions 63, 64, 65, 66 are provided respectively between N well 16 and P well 14.

Parasitic resistance and parasitic capacitance in the well per one charge transfer portion can thus be reduced by arranging a plurality of charge transfer portions in divided blocks. In the third embodiment, four charge transfer portions are provided so that parasitic resistance and parasitic capacitance in N well 16 and P well 14 will be reduced to a quarter in one imaginary block. Since delay in charge movement due to parasitic resistance and parasitic capacitance is determined by the product of these two, the delay in charge movement from N well 16 to P well 14 can be reduced to one-sixteenth. Needless to say, larger number of charge transfer portions will further reduce the delay in charge movement.

N well potential control portion 1 includes well potential detecting circuit 20 monitoring Vbn of N well 16, RS flip-flop circuit 28 setting signal ZACTN high or low in response to signal DETP1 from well potential detecting circuit 20a, and inverting circuit 29 inverting signal ZACTN to output signal ACTN. As other internal configurations are the same as in N well potential control portion 1 in FIG. 3 of the first embodiment, detailed description will not be repeated.

P well potential control portion 2 includes well potential detecting circuit 20a monitoring Vbp of P well 14. As other internal configurations are the same as in P well potential control portion 2 in FIG. 3 of the first embodiment, detailed description will not be repeated.

Well potential detecting circuit 20 and well potential detecting circuit 20a are formed on wells 91, 92 respectively, to which the VT model is not applied in order to ensure an accurate operation without varying a threshold voltage of the transistor constituting the well potential detecting circuit, and of which potential is controlled to a constant level irrespective of modes. Here, each of wells 91, 92 generically represents a P well having the N channel MOS transistor formed therein and an N well having the P channel MOS transistor formed therein.

Next, an operation of semiconductor device 202 in the transition from the stand-by mode to the active mode, when an amount of excess charges in the N well is smaller than that required in the P well, will be described. As operations of N well potential control portion 1, P well potential control portion 2 and charge transfer portions 63, 64, 65, 66 in the stand-by mode as well as N well potential control portion 1 and P well potential control portion 2 in the active mode are the same as in the first embodiment, detailed description will not be repeated.

In the active mode, each of charge transfer portions 63, 64, 65, 66 that are connected in parallel is commonly activated upon receiving control signal PDE. The excess charges in N well 16 are fed to P well 14 requiring charges via charge transfer portions 63, 64, 65, 66 that are connected in parallel. Thereafter, when Vbp=VbpS is achieved, signal ZACTN is output from RS flip-flop circuit 28. Signal ZACTN is inverted by inverting circuit 29 to provide signal ACTN. Signal ACTN inactivates charge transfer portions 63, 64, 65, 66, and charge transfer is completed.

As described above, according to the third embodiment, semiconductor device 202 adapted to an example in which an amount of excess charges in the N well is smaller than that required in the P well can reduce the delay in charge movement in the transition from the stand-by mode to the active mode, compared to semiconductor device 201a in FIG. 3 of the first embodiment. Therefore, a time period for controlling the well potential as well as a time period for transition from the stand-by mode to the active mode can be shortened.

The well potential in each block is considered to vary in a similar manner. Therefore, if the device is configured such that only one divided block is monitored as in the third embodiment, area required for a control system can be reduced. In addition, potential distribution within the well can be suppressed on the whole, because charge transfer is controlled in the divided blocks.

Well potential detecting circuit 20 and well potential detecting circuit 20a are formed on wells 91, 92 respectively, to which the VT model is not applied. Therefore, the threshold voltage of the transistor constituting the well potential detecting circuit does not fluctuate, and accurate controlling of the well potential can be realized.

In the third embodiment, N well potential control portion 1, charge transfer portions 63, 64, 65, 66, and P well potential control portion 2 in semiconductor device 202 have the same configuration as N well potential control portion 1, charge transfer portion 3a and P well potential control portion 2 in semiconductor device 201a in FIG. 3 respectively. However, if N well potential control portion 1, charge transfer portions 63, 64, 65, 66, and P well potential control portion 2 have the same configuration as those in semiconductor device 201b in FIG. 7 or semiconductor device 201c in FIG. 8 respectively, charge transfer portions 63, 64, 65, 66 are applicable as charge transfer portion 3b in FIG. 7 or charge transfer portion 3c in FIG. 8.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device having a plurality of modes, comprising:
a CMOS logic circuit having a plurality of transistors formed on an N well and a P well respectively;
a first potential control portion controlling a potential of said N well to a first target potential preset for each of said plurality of modes, in each of said modes;
a second potential control portion controlling a potential of said P well to a second target potential preset for each of said plurality of modes, in each of said modes; and
a charge transfer portion electrically connecting between said N well and said P well, in response to a prescribed mode transition between said plurality of modes.

2. The semiconductor device according to claim 1, wherein
said semiconductor device makes a transition from an operation mode to a waiting mode in response to said prescribed mode transition, said first target potential of said N well is accordingly set in said waiting mode higher than in said operation mode, and said second target potential of said P well is set in said waiting mode lower than in said operation mode.

3. The semiconductor device according to claim 1, wherein
said charge transfer portion operates based on a detected result of a potential of at least one of said N well and P well.

4. The semiconductor device according to claim 1, wherein
at least one of said first potential control portion and said second potential control portion includes a well potential control circuit, and
during a period in which said charge transfer portion electrically isolates between said N well and said P well, said well potential control circuit varies a potential of the corresponding well to a prescribed value when said potential of the corresponding well has not reached said prescribed value, until the prescribed value is achieved.

5. The semiconductor device according to claim 1, wherein
said charge transfer portion releases excess charges from said N well to said P well as needed in said prescribed mode transition.

6. The semiconductor device according to claim 1, wherein
said charge transfer portion includes a switching circuit and a resistance portion connected in series between said N well and said P well, and
said switching circuit electrically connects said N well to said P well in response to said prescribed mode transition through said resistance portion.

7. The semiconductor device according to claim 1, further comprising a power supply interconnection supplying a prescribed voltage controlled to a constant level; wherein
said charge transfer portion includes
a discharging circuit connected between said N well and said power supply interconnection and releasing excess charges of said N well to said power supply interconnection in response to said prescribed mode transition, and
a charge injection circuit connected between said power supply interconnection and said P well and injecting charges from said power supply interconnection to said P well in response to said prescribed mode transition.

8. The semiconductor device according to claim 1, wherein
each of said N well and P well is imaginarily divided into a plurality of blocks,
said N well includes a plurality of first connection portions corresponding to said plurality of blocks respectively,
said P well includes a plurality of second connection portions corresponding to said plurality of blocks respectively,
each of said plurality of first connection portions is electrically connected to said first potential control portion,
each of said plurality of second connection portions is electrically connected to said second potential control portion, and
said charge transfer portion is provided corresponding to each of said plurality of blocks and arranged between corresponding one of said plurality of first connection portions and corresponding one of said plurality of second connection portions.

9. The semiconductor device according to claim 8, wherein
said first potential control portion and said second potential control portion are formed on another P well and another N well, of which potential is controlled to a constant level irrespective of said plurality of modes.
